(19) United States
(12) Patent Application Publication
(10) Pub. No.: US 2008/0225483 A1
(43) Pub. Date: Sep. 18, 2008

(54) FRAME MOUNTED MODULAR HYBRID COOLING SYSTEM

(75) Inventors: William C. Kahn, Denton, TX (US); Glen A. Marshall, Aubrey, TX (US); Travis W. Leigh, Fort Worth, TX (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: PACCAR INC, Bellevue, WA (US)

(21) Appl. No.: 11/686,786

(22) Filed: Mar. 15, 2007

(51) Int. Cl. G06F 1/20; H05K 7/20

(52) U.S. Cl. 361/699; 361/689; 361/699; 903/940

(57) ABSTRACT

A modular cooling system (10) for a vehicle is provided. The modular cooling system (10) includes a frame (12) adapted to be mounted to a portion of a vehicle. A heat-generating component (16) and a plurality of cooling components (18, 22, 24, 26) are received on the frame (12). At least one of the cooling components (18, 22, 24, 26) is placed into communication with the heat-generating component (16).

### BACKGROUND

Hybrid drive vehicles, which use both electrical and internal combustion engine power, include certain power electronic devices that convert, manage, and distribute power and energy in hybrid vehicle applications. These devices, such as semiconductors, converters/inverters, battery packs, controllers, and switches, are important to developing an efficient and high-performance hybrid vehicle system. For instance, in heavy hybrid vehicles, converters and inverters condition and control the electrical signal between the energy storage unit (such as the battery pack) and the motor/generator to provide power to various components at critical times.

Hybrid drive vehicles need proper thermal management of the hybrid components for optimum performance and durability. Therefore, hybrid vehicles typically require supplemental cooling loops, separate from the primary engine, to maintain a proper operating temperature for the heat-generating components of the hybrid drive system. Typically, the components of a cooling system are individually mounted to the vehicle in a suitable location for cooling the desired component. The cooling components are thereafter placed into fluid communication with a coolant loop or coolant lines and heat-generating components. The necessary electrical systems must also be installed for controlling the cooling components.

Separately installing each cooling component and associated electrical control system increases installation time and cost. Moreover, planning the location for each cooling component relative to the heat-generating components can take significant amounts of time, especially when installing the components on various vehicle models. These installation and design costs contribute to the overall cost of manufacturing the vehicle, thus increasing the cost to the purchaser or reducing the profit of the manufacturer. It is desired to have a cooling system that can be used to cool a variety of heat-generating components and mounted to a variety of different vehicles in a simplified manner to reduce installation time and costs.

### SUMMARY

A modular cooling system for a vehicle is provided. The modular cooling system includes a frame adapted to be mounted to a portion of a vehicle. A heat-generating component and a plurality of cooling components are received on the frame. At least one of the cooling components is placed into fluid communication with the heat-generating component.

A method for providing a cooling system for cooling a heat-generating component of a vehicle is also provided. The method includes securing a heat-generating component on a frame, securing a plurality of cooling components on the frame, placing at least one of the cooling components into fluid communication with the heat-generating component, and mounting the frame to the vehicle.

By installing and plumbing the cooling components and the heat-generating component prior to mounting the frame to the vehicle, vehicle assembly costs are minimized. Rather than securing each component individually to the vehicle and thereafter placing the component into communication with the other components, the components are mounted to the vehicle in one step. Moreover, packaging the cooling system together with the heat-generating component allows the cooling system to be mounted in a variety of locations on the vehicle and on a variety of different vehicles.

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is an environmental view of a representative embodiment of a modular cooling system mounted to a truck constructed in accordance with one embodiment of the present disclosure;

FIG. 2 is an environmental view of the modular cooling system of FIG. 1 mounted to the frame rail of a truck;

FIG. 3 is an isometric view of the modular cooling system of FIG. 1; and

FIG. 4 is an exploded view of the modular cooling system of FIG. 1.

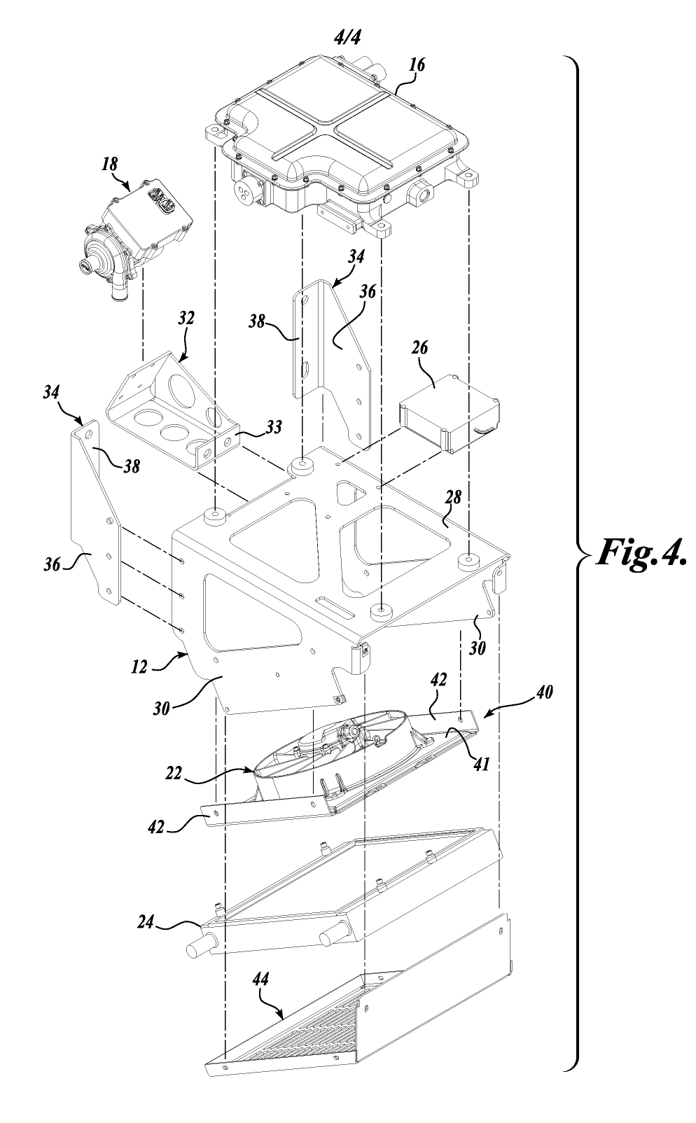

### DETAILED DESCRIPTION

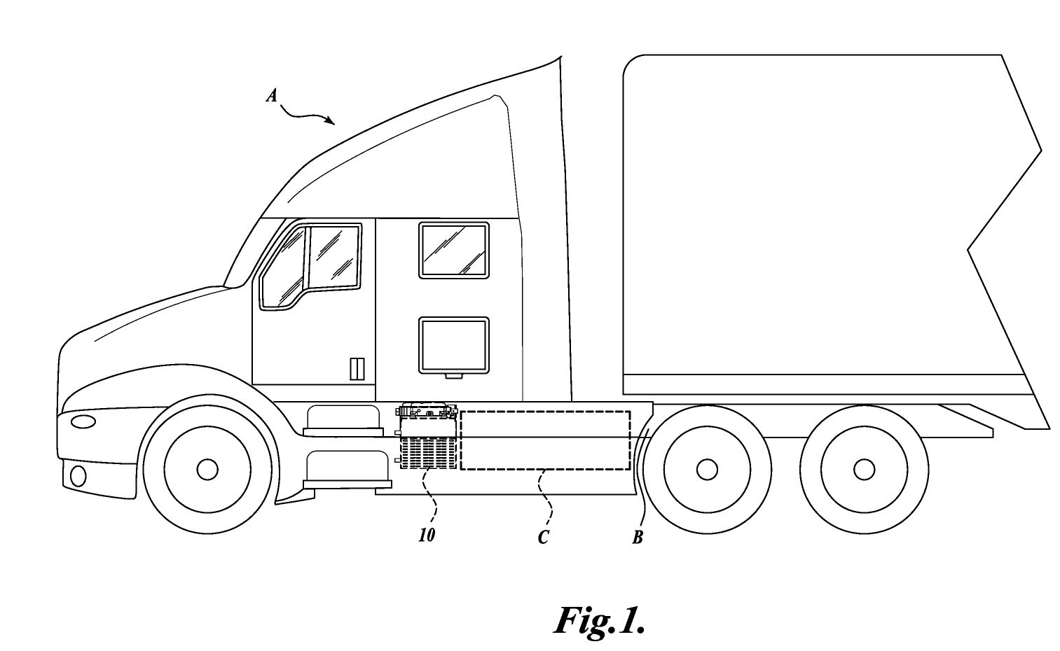

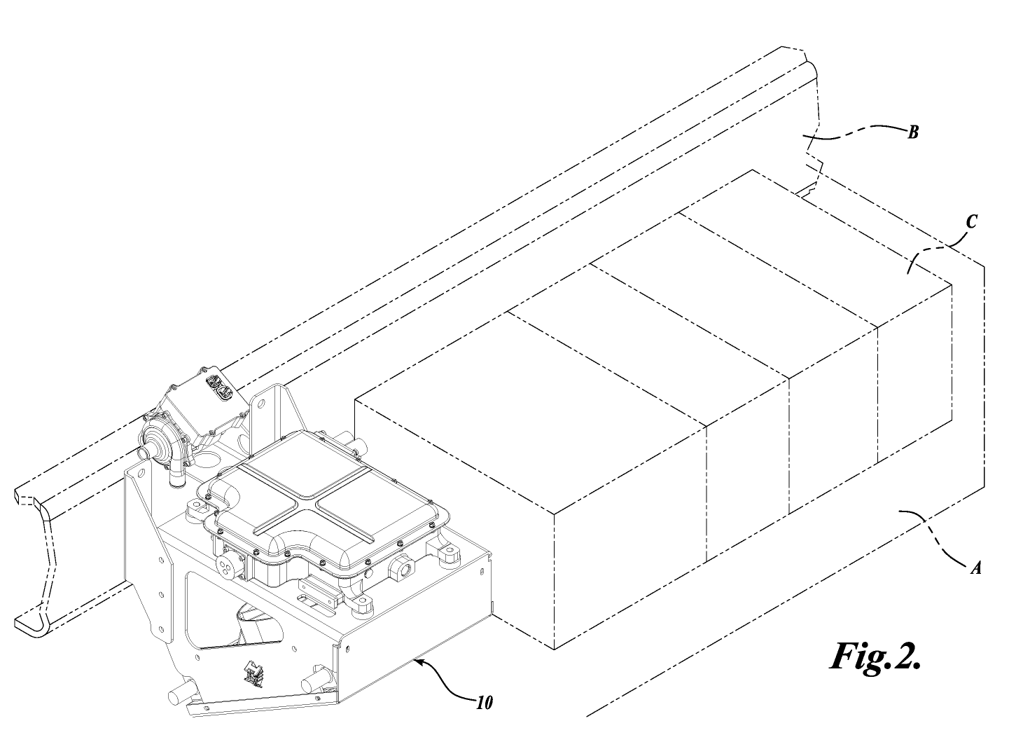

A modular cooling system 10 constructed in accordance with one embodiment of the present disclosure is best seen by referring to FIGS. 1 and 2. The modular cooling system 10 is shown secured to a portion of a truck A; however, it should be appreciated that placement of the modular cooling system 10 is not so limited, with other mounting locations being within the scope of the present disclosure. From time to time throughout this specification, directional terms, such as vertical, horizontal, top, bottom, etc., are used in the description of various components. It should be apparent that the use of such terms is merely for convenience and, as such, is not intended to limit the embodiments or claims contained herein. The modular cooling system 10 may be mounted to any suitable portion of the truck A. In the embodiment of FIG. 1, the modular cooling system 10 is secured to a frame rail B of the truck A behind the cab D and in front of the fuel tank C.

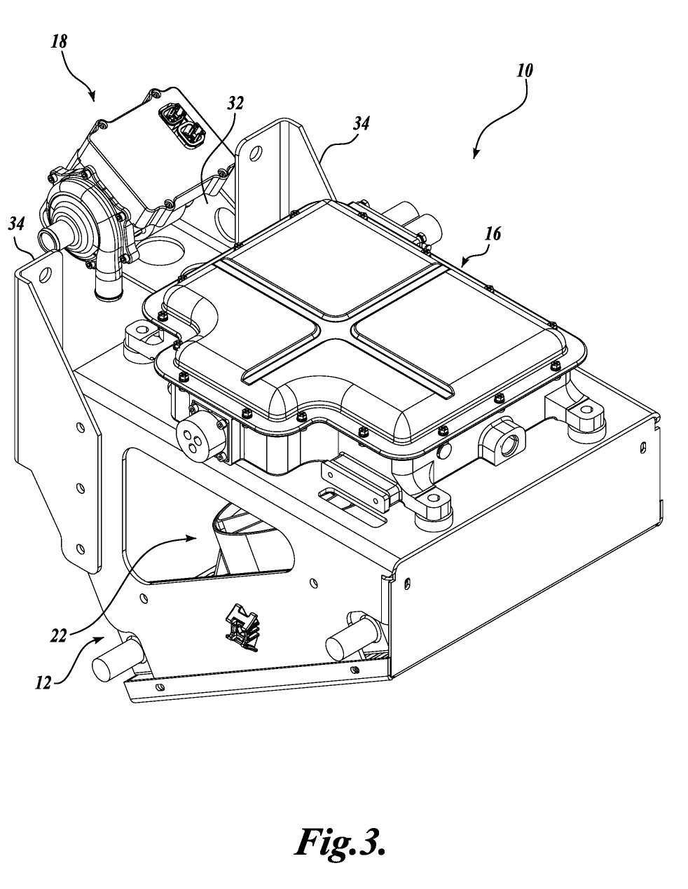

Referring to FIG. 3, the illustrated modular cooling system 10 includes a plurality of cooling components that cool at least one heat-generating vehicle component. The heat-generating component is integrated within the modular cooling system 10 such that it may be placed into fluid communication with the plurality of cooling components. FIG. 3 depicts the heat-generating component as an inverter 16 for a hybrid vehicle. Other components may be cooled in addition to or instead of the inverter 16. For instance, the modular cooling system 10 may include heat-generating components in the form of a down converter, a battery pack, a semiconductor, a controller, a switch, etc.

The cooling components of the modular cooling system 10 are packaged together on a suitable frame 12. The cooling components include, but are not limited to, a coolant pump 18 (with an optional integrated controller), a cooling fan 22, a heat exchanger 24, and a fan controller 26. The cooling components may be any suitable off-the-shelf components that are adapted to cooperate and sufficiently cool the heat-generating component(s), such as the inverter 16. Other cooling components may be included in the modular cooling system 10 in addition to or instead of the cooling components listed above. For instance, the system may include a cooling reservoir or additional fans or heat exchangers.

Referring to FIGS. 2 and 3, the frame 12 may be of a size and shape designed to receive the heat-generating component and the cooling components. The illustrated frame 12 has an inverted U-shape in cross-section such that it includes a horizontal portion 28 and two vertical side portions 30 extending downwardly therefrom. The frame 12 may include a plurality of openings formed in the horizontal portion 28 and the vertical side portions 30 such that components may be easily mounted beneath or inside the frame 12 and air may flow throughout the modular cooling system 10. A pair of mounting brackets 34 are secured to the forward portion of the frame 12 for mounting the frame 12 to the vehicle frame rail B. The mounting brackets 34 may be any suitable shape and size. An exemplary bracket 34 is preferably L-shaped in cross-section and includes a side portion 36 and a forward portion 38. A plurality of fasteners (not shown) pass through the side portion 36 and the vertical side portion 30 to couple the mounting bracket 34 to the frame 12. The forward portion 38 is adapted to receive a plurality of fasteners to couple the forward portion 38 to the frame rail B, thereby securing the frame 12 to the frame rail B. It should be appreciated that the frame 12 may instead be mounted to the frame rail B or another portion of the truck A in any other well-known manner.

In the alternative, the frame 12 may be a suitable platform device that is adapted to receive the heat-generating component and the cooling components thereon. The platform device may be formed from a sheet of material, such as metal, that is either bent at the edges or includes mounting brackets secured thereto for mounting the platform horizontally to the frame rail B. A plurality of fasteners may be used to secure the components to the platform.

A separate bracket may be secured to the frame 12 for mounting any of the various components to the frame 12. For instance, a pump bracket 32 is used to mount the coolant pump 18 to the frame 12. The pump bracket 32 is adapted to receive the coolant pump 18 and secure it to the frame 12 such that the pump 18 may be placed into communication with the other components. Preferably, the pump bracket 32 includes a flange 33 that is mounted to the forward portion 38 of either mounting bracket 34.

The cooling fan 22 may be secured to the frame 12 with a fan bracket 40. The fan bracket 40 includes a fan-receiving portion 41 for receiving the cooling fan 22 therewithin and side flanges 42 formed on each side of the fan-receiving portion 41. The side flanges 42 are mateable with the vertical side portions 30 of the frame 12. The fan controller 26 is mounted in any suitable manner to the interior surface of the frame 12 such that it may be placed into electrical communication with the fan 22. The heat exchanger 24 is mounted to the bottom of the fan bracket 40 with a plurality of fasteners, and a grill 44 is secured to the frame 12 to substantially enclose the fan 22 and heat exchanger 24 within the frame 12.

The inverter 16 is suitably mounted to the horizontal portion 28 of the frame 12 such that it may be placed into communication with the cooling components. The inverter 16 is coupled to the exterior surface of the horizontal portion 28 of the frame 12. In this manner, the inverter 16 is accessible such that it may be easily placed into electrical communication with other vehicle components. It should be appreciated that the inverter 16 may instead be mounted to any portion of the frame 12. Moreover, other heat-generating components may also be suitably mounted to the frame 12.

The frame 12, brackets 32, 34, and 40, and grill 44 are made from any suitable material, such as sheet metal. It should be appreciated that frame 12, brackets 32, 34, and 40, and grill 44 may be formed in any suitable shape and size such that the cooling components and the heat-generating components are mountable within the frame 12 to package all the components into a modular cooling system 10.

The frame 12 may be mounted to the vehicle A such that it provides structural support for the vehicle or other vehicle components. For instance, the frame 12 may include a pair of steps (not shown) mounted to its exterior such that when the system 10 is mounted beneath the truck cab B, a user could climb the steps to access upper portions of the cab exterior. The frame 12 may also include mounting features for securing other vehicle components to the frame 12. In this manner, the frame rail B could be reserved for other components, such as larger fuel tanks.

To use the modular cooling system 10, the cooling components and heat-generating components are mounted to the frame 12 in the manner described above. The coolant pump 18, heat exchanger 24, and inverter 16 are placed into fluid communication with coolant lines (not shown) to define a coolant loop within the modular cooling system 10. A suitable coolant is thereafter added to the coolant loop in a manner well known in the art. The components are also wired together as necessary in a manner well-known in the art.

After securing the components to the frame 12 and placing the components into fluid and/or electrical communication with each other, the frame 12 is mounted to the frame rail B by securing the mounting brackets 34 to the frame rail B. The electrical components are thereafter placed into electrical communication with a power source on the vehicle (not shown). It should be appreciated that the electrical components may instead be placed into electrical communication with a power source on the frame 12 before the frame 12 is mounted to the vehicle. If needed, the cooling components may also be placed into fluid communication with other heat-generating components on the vehicle A.

Packaging the components together as a single modular cooling system 10 allows an operator to mount the cooling components and the heat-generating component to the vehicle in a single installation. Having the ability to mount the components to the vehicle at one time in a single installation, as well as being able to wire and plumb the components prior to installation, reduces manufacturing time and costs.

While illustrative embodiments have been illustrated and described, it will be appreciated that various changes can be made therein without departing from the spirit and scope of the invention.

The embodiments of the invention in which an exclusive property or privilege is claimed are defined as follows:

1. A modular cooling system for a vehicle, comprising:
(a) a frame adapted to be mounted to a portion of a vehicle;
(b) a heat-generating component received on the frame; and
(b) a plurality of cooling components received on the frame, wherein at least one of the cooling components is placed into fluid communication with the heat-generating component.

2. The modular cooling system of claim 1, wherein at least one of the cooling components and the heat-generating component are placed into fluid communication with coolant lines.

3. The modular cooling system of claim 1, further comprising coolant added to at least one of the cooling components.

4. The modular cooling system of claim 1, wherein the cooling components include a coolant pump, a cooling fan, and a heat exchanger.

5. The modular cooling system of claim 1, wherein the heat-generating component is an inverter.

6. The modular cooling system of claim 1, further comprising a plurality of heat-generating components secured to the frame.

7. The modular cooling system of claim 1, further comprising a vehicle component secured to the frame.

8. The modular cooling system of claim 1, wherein the frame is mountable to a side rail of the vehicle.

9. A method for providing a cooling system for cooling a heat-generating component of a vehicle, the method comprising:
(a) securing a heat-generating component on a frame;
(b) securing a plurality of cooling components on the frame;
(c) placing at least one of the cooling components into fluid communication with the heat-generating component; and
(d) mounting the frame to the vehicle.

10. The method of claim 9, wherein at least one of the cooling components and the heat-generating component are placed into fluid communication with coolant lines.

11. The method of claim 9, further comprising adding coolant to at least one of the cooling components prior to mounting the frame to the vehicle.

12. The method of claim 9, further comprising placing at least one of the cooling components and the heat-generating component into electrical communication with a power source.

13. The method of claim 9, wherein the cooling components include a coolant pump, a cooling fan, and a heat exchanger.

14. The method of claim 9, wherein the heat-generating component is an inverter.

15. The method of claim 9, further comprising securing a plurality of heat-generating components to the frame and thereafter placing the heat-generating components into fluid communication with at least one of the cooling components.

16. The method of claim 9, further comprising mounting a vehicle component to the frame.

17. The method of claim 9, wherein the mounting step comprises mounting the frame to a side rail of the vehicle.
